(19) United States
(12) Patent Application Publication
(10) Pub. No.: US 2017/0170362 A1
(43) Pub. Date: Jun. 15, 2017

(54) Patterned Wafer

(71) Applicant: Rubicon Technology, Inc., Bensenville, IL (US)

(72) Inventors: Sangjin Yoon, Buffalo Grove, IL (US); Jang-Ho Seo, Bensenville, IL (US)

(21) Appl. No.: 14/967,576

(22) Filed: Dec. 14, 2015

(51) Int. Cl. H01L 33/22; H01L 33/00; H01L 33/32

(52) U.S. Cl. CPC H01L 33/22; H01L 33/32; H01L 33/007

(57) ABSTRACT

A sapphire wafer has a patterned top surface (of sapphire) with a plurality of protrusions. Specifically, the plurality of protrusions includes a set of first protrusions and a set of second protrusions, and at least three first protrusions are adjacent to each other. As such, these three first protrusions define a primary interstitial region therebetween. At least one of the second protrusions is in the primary interstitial region.

### FIELD OF THE INVENTION

Illustrative embodiments of the invention generally relate to wafers and, more particularly, to patterned oxide wafers used for electronic applications.

### BACKGROUND OF THE INVENTION

Solid state light emitting diodes (“LEDs”) are rapidly gaining acceptance in the broad marketplace. They have a wide variety of uses in the lighting and illumination areas, including in lightbulbs, traffic lights, televisions, control consoles, and automobile headlights. Among other advantages, when compared to conventional incandescent light sources, LEDs typically consume less power, have a smaller profile, switch more rapidly, and have a longer life span. Their price also continues to decrease, further contributing to their growing adoption rate.

Modern solid state LEDs typically are formed on a substrate that plays an important role in enhancing their performance. For example, the substrate has an impact on the ultimate brightness of an LED.

### SUMMARY OF VARIOUS EMBODIMENTS

In accordance with one embodiment of the invention, a sapphire wafer has a patterned top surface (of sapphire) with a plurality of protrusions. Specifically, the plurality of protrusions includes a set of first protrusions and a set of second protrusions, and at least three first protrusions are adjacent to each other. As such, these three first protrusions define a primary interstitial region therebetween. At least one of the second protrusions is in the primary interstitial region.

Various embodiments can implement a number of different variants to this theme. For example, the top surface may have a substantially flat portion, and the first protrusions and second protrusions each may have walls that are non-orthogonal to the substantially flat portion of the top surface. More specifically, at least some of the walls can form an angle of greater than about 90 degrees with the substantially flat portion of the top surface. Alternatively or in addition, the first protrusions may have a first height and the second protrusions have a second height. The first height preferably is greater than the second height. In this and other embodiments, the at least three first protrusions may include a number of different first protrusions, such as three or four protrusions, to form the primary interstitial region.

As adjacent members, at least three first protrusions may include two outer portions. A first of the two outer portions is adjacent to a first corresponding outer portion of one of the other first protrusions and, in a similar manner, a second of the two outer portions is adjacent to a second corresponding outer portion of another of the other first protrusions. The at least one second protrusion is positioned between the at least three first protrusions.

The sapphire wafer may include a number of additional layers that cooperate to form a device. To that end, the sapphire wafer also may have LED layers, supported by the top surface, to at least partly form an LED 20. Among other things, the LED layers may include gallium nitride.

The interstitial region may form smaller interstitial regions. For example, the noted at least one second protrusion and at least one of the first protrusions may form a nested interstitial region therebetween. In that case, the primary interstitial region includes the nested interstitial region, and the top surface also has a set of third protrusions. At least one third protrusion is positioned in the nested interstitial region.

Like some other embodiments, the top surface may have a substantially flat portion. In that case, the first protrusions may have a circular or elliptical shape along a plane parallel with the substantially flat portion. Indeed, other protrusion embodiments may have other shapes in that plane. Those portions may be considered to form a base for the first protrusions. In that case, at least three first protrusions each may have respective first maximum outer dimensions at their respective bases. In a similar manner, the at least one second protrusion also has a base with a second maximum outer dimension. Each of the first maximum outer dimensions may be greater than each of the second maximum outer dimensions.

In accordance with another embodiment of the invention, a sapphire wafer has a patterned top surface (of sapphire) with a substantially flat portion and a plurality of protrusions extending from the substantially flat portion. The plurality of protrusions includes a set of first protrusions and a set of second protrusions. Each of the first protrusions is considered to have a first base intersecting the substantially flat portion, and each first base has a first maximum outer dimension. In a corresponding manner, the second protrusions each are considered to have a second base intersecting the substantially flat portion, and each second base has a second maximum outer dimension. At least one of the second protrusions is positioned between at least two first protrusions. The first maximum outer dimensions of the at least two first protrusions preferably are greater than the second maximum outer dimension of the at least one second protrusion.

In accordance with other embodiments, a method provides an oxide wafer having a top surface of oxide, and patterns the top surface to have a plurality of protrusions. The plurality of protrusions includes a set of first protrusions and a set of second protrusions. Three first protrusions are adjacent to each other and define a primary interstitial region therebetween. One of the second protrusions is in the primary interstitial region.

Various embodiments of the method can use a number of different techniques to form the protrusions. For example, to pattern the top surface, some embodiments use a photolithographic process.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a light bulb that may be configured in accordance with illustrative embodiments of the invention.

FIG. 2 schematically shows a light emitting diode die (“LED die”) that may be used with the light bulb of FIG. 1.

FIG. 3 schematically shows a cross-sectional view of the LED die of FIG. 2.

FIG. 4A schematically shows a plan view of the patterned sapphire substrate of FIG. 4A configured in accordance with illustrative embodiments of the invention.

FIG. 4B schematically shows a cross-sectional view of the patterned sapphire substrate configured in accordance with illustrative embodiments of the invention.

FIG. 4C schematically shows light rays reflecting from the cross-sectional view of the patterned sapphire substrate of FIG. 4A.

FIG. 4D schematically shows a patterned sapphire substrate in accordance with alternative embodiments of the invention.

FIG. 5 shows a process of forming the patterned sapphire substrate of FIG. 4A in accordance with illustrative embodiments of the invention.

FIG. 6A schematically shows an un-patterned sapphire substrate at step 500 of FIG. 5.

FIG. 6B schematically shows the un-patterned sapphire substrate of FIG. 6A with a photoresist layer in accordance with step 502 of FIG. 5.

FIG. 6C schematically shows a mask used to pattern the photoresist layer in accordance with step 504 of FIG. 5.

FIG. 7 schematically shows a cross-sectional view of the patterned sapphire substrate configured in accordance with alternative embodiments of the invention.

### DESCRIPTION OF ILLUSTRATIVE EMBODIMENTS

Illustrative embodiments of the invention process a sapphire substrate to significantly improve light output of a light emitting diode formed on its top surface. More specifically, such embodiments pattern the top surface of the sapphire substrate to have features that more efficiently reflect downwardly directed light in a desired direction. For example, the top surface may have more closely positioned protrusions with angled walls that reflect downwardly directed light in a generally upward direction. Details of illustrative embodiments are discussed below.

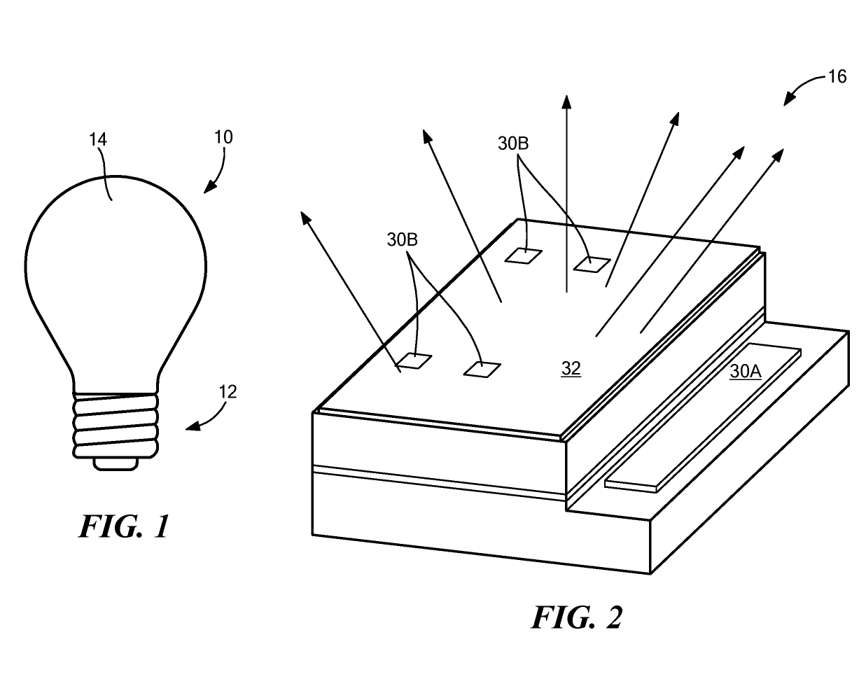

FIG. 1 schematically shows a light bulb 10 that may be configured in accordance with illustrative embodiments of the invention. As shown, the light bulb 10 has an interface 12 for connecting with an energy source, and an at least partially transparent body 14 for both directing light generated by an internal light source and protecting the internal light source. In illustrative embodiments, the internal light source is a light emitting diode die (“LED die 16”) configured in accordance with illustrative embodiments of the invention.

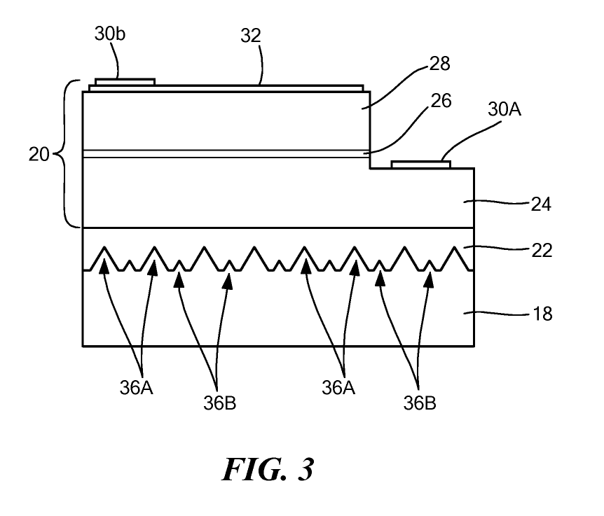

FIG. 2 schematically shows a perspective view of the noted LED die 16, while FIG. 3 schematically shows a cross-sectional view of the LED die 16 of FIG. 2. As shown, the LED die 16 has a monolithic body fabricated of multiple layers of material. Specifically, the LED die 16 has a substrate 18 upon which the noted remaining plurality of additional layers are formed. In illustrative embodiments, the substrate 18 includes a patterned oxide material, such as sapphire, configured to better reflect light in accordance with illustrative embodiments of the invention. FIG. 3 more clearly shows the pattern—a plurality of protrusions 36A and 36B (discussed below) extending from the top surface of the substrate 18. As discussed in greater detail below, these protrusions 36A and 36B improve the overall brightness of the LED die 16.

The patterned substrate 18 may be considered to support a generally planar LED 20 on an intervening buffer layer 22. Among other things, the buffer layer 22 provides a similar lattice constant with the upper layers (e.g., gallium nitride layers, discussed below) to reduce dislocations that may occur with the substrate 18 (i.e., the buffer layer 22 reduces lattice mismatches). In addition, the buffer layer 22 effectively protects or isolates the LED 20 from thermal mismatches between the material forming the LED 20 and the substrate 18. In addition, the buffer layer 22 ensures that the LED layers more smoothly and consistently fabricated in a planar form factor on the substrate 18. Those skilled in the art can select any of a number of appropriate materials to form the buffer layer 22. For example, the buffer layer 22 may include undoped gallium nitride (GaN), or aluminum nitride (AlN) epitaxially grown on the top surface of the substrate 18. If formed as an epitaxial layer, the buffer layer 22 should have a crystal structure like that of the substrate 18. Other embodiments, however, may or may not form the buffer layer 22 (and/or other layers) epitaxially.

Although the LED 20 has a number of other layers, it is mainly composed of three principal layers. Specifically, continuing from the bottom upwardly, the LED 20 has a cathode layer 24 that interacts with an active layer 26 (also known as an “active region”), and a top anode layer 28. In a manner similar to the buffer layer 22, those skilled in the art can select the appropriate materials for forming these three principal layers. That selection can be based on a number of factors, including the anticipated environment in which the LED 20 will operate. For example, illustrative embodiments may form the various layers from the following materials:
Cathode layer 24: N-doped gallium nitride,
Active layer 26: indium gallium nitride,
Anode layer 28: P-doped gallium nitride.

Of course, those skilled in the art can select other materials for these layers. Accordingly, like other layers, discussion of the specific materials is not intended to limit various embodiments of the invention.

The three layers discussed above must receive energy to generate light. To that end, the LED 20 also has one or more cathode pads 30A in direct conductive contact with the cathode layer 24, and one or more anode pads 30B in direct conductive contact with the anode layer 28. Each one of the pads 30A and 30B preferably is formed from a highly conductive material, such as gold or a doped semiconductor.

The LED 20 also has a current spreading electrode 32 between the anode pad 30B and the anode layer 28 to more efficiently spread current across the anode layer 28. In addition, this current spreading electrode 32 should not block light and thus, preferably is substantially transparent to the wavelengths of light generated by the LED 20. For example, those skilled in the art may use indium tin oxide to form the transparent electrode. Of course, in a manner similar to the materials discussed for the other layers, those skilled in the art can select other materials that may more appropriately satisfy the requirements of a given application.

During use, a power source applies an appropriate voltage across the anode layer 28 and cathode layer 24 through the pads 30A and 30B. At this point, the LED 20 is considered to be in a “forward biased” state. As a result, positive charge carriers (i.e., holes) and negative charge carriers (i.e., electrons) migrate toward each other into the active layer 26. When they collide/interact, the positive charged carriers and negative charge carriers release energy, which manifests in the form of photons. This process, known in the art as electroluminescence, produces light having a wavelength based upon the energy band gap of the gallium nitride.

As a substantially planar device, a significant amount of light that the LED 20 produces is directed either generally upwardly or generally downwardly. Absent modification to the device itself, however, much of the downwardly directed light would be absorbed by the sapphire substrate 18. The inventors recognized this problem and, in response, developed a solution that efficiently and effectively redirects much of the downwardly directed light back upwardly. Accordingly, that recovered light substantially enhances the output brightness of the LED die 16.

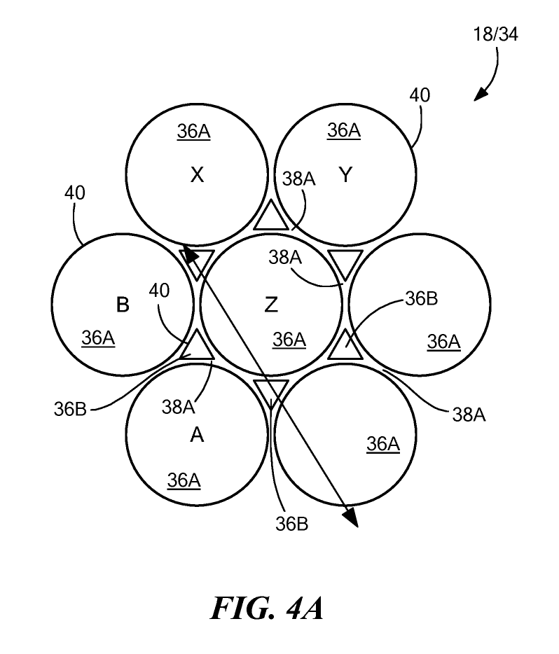

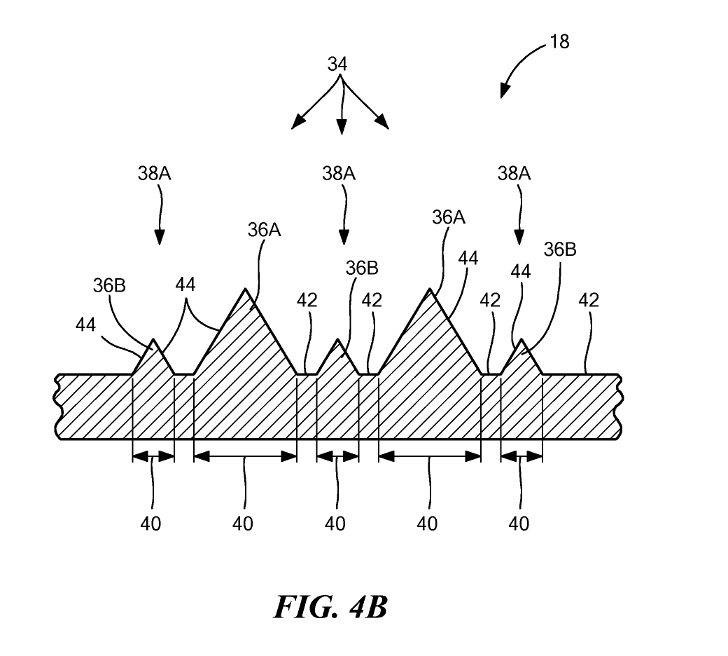

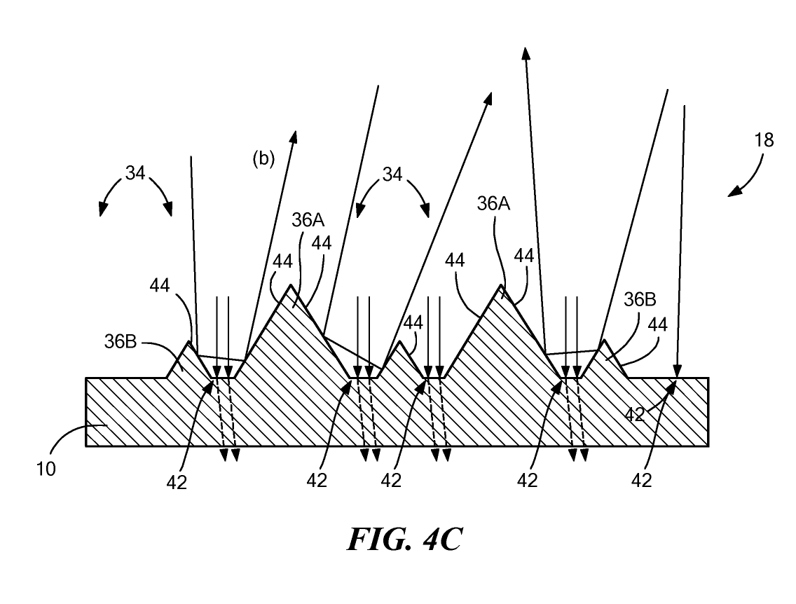

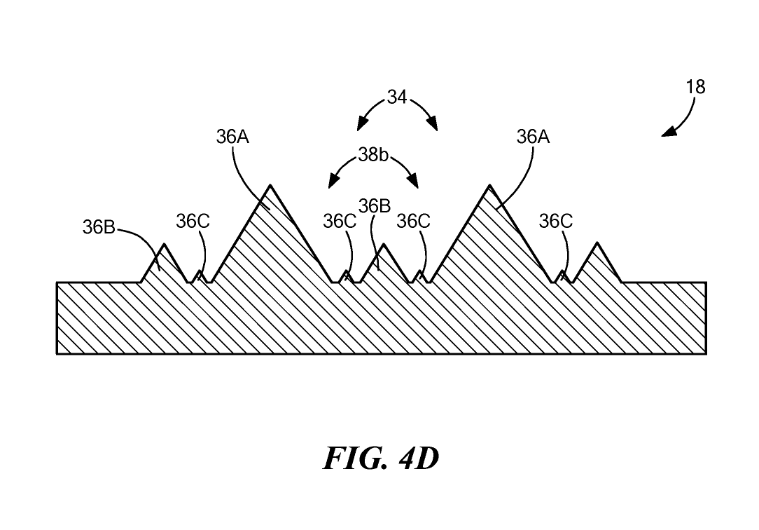

Specifically, to overcome this problem and improve LED performance, the sapphire substrate 18 has a top surface 34 with a pattern of protrusions 36A and 36B configured to more efficiently reflect light upwardly. FIG. 4A schematically shows these features more clearly by depicting a plan view of a portion of the patterned substrate 18. It should be noted that this figure shows only the substrate 18—not other layers, such as the additional buffer layer 22 and LED 20. FIG. 4B also schematically shows a cross-sectional view of the substrate 18 of FIG. 4A across the double-arrowed line in FIG. 4B, but with an additional small protrusion 36B (discussed below).

It should be noted that FIG. 4A only shows a small portion of the top surface 34 of the sapphire substrate 18. Those skilled in the art should understand that this pattern preferably continues and repeats across all or much of the rest of the top surface 34. For example, the pattern can have a uniform or consistent pattern of protrusions 36A and 36B across the top surface 34 of the substrate 18. Such a pattern, for example, may expand from that in FIG. 4A. Alternatively, the pattern can be random, or have portions that each form different patterns (e.g., four portions that each has a different pattern). In either case, the small portion of FIG. 4A is shown for simplicity purposes only.

As shown, the substrate 18 has a plurality of large protrusions 36A that substantially surround a plurality of small protrusions (referred to as “small protrusions 36B”). More specifically, at least three of the large protrusions 36A are adjacent to each other and, accordingly, form an interstitial region 38A. In other words, the interstitial region 38A of this embodiment forms between the three adjacent large protrusions 36A. Other embodiments, however, may form the interstitial region 38A between more adjacent large protrusions 36A (e.g., four large protrusions 36A). In accordance with preferred embodiments of the invention, the interstitial region 38A contains at least one small protrusion 36B.

To illustrate this point, three adjacent large protrusions 36A in FIG. 4A have been marked with the letters “X,” “Y,” and “Z.” Clearly, each one of these three large protrusions 36A is adjacent to the other two. Specifically, using compass designations of north/south/east/west for convenience, the large protrusion marked Z is adjacent to large protrusion X at its northwest boundary/outer portion, and large protrusion Y at its northeast boundary/outer portion. In a similar manner, large protrusions X and Y are adjacent near their middle portions (i.e., the east portion of large protrusion X and the west portion of large protrusion Y).

Portions of these large protrusions 36A thus are adjacent to each other even though small protrusions 36B are between other portions of those large protrusions 36A. Accordingly, since they have adjacent portions, these large protrusions X, Y, and Z are next to each other—they are neighbors. A substantially planar/flat portion 42 of the top surface 34 of the substrate 18 also extends between them. FIG. 4B, for example, more clearly shows substantially planar or flat portions 42 on the top surface 34 between the large protrusions 36A. Moreover, no other protrusion 36A of like size is partially or fully between adjacent large protrusions 36A. In this embodiment, their interstitial region 38A has a single small protrusion 36B.

To further highlight the nature of adjacency, additional large protrusions 36A in FIG. 4A are marked with the letters “A” and “B.” Clearly, although large protrusion A is adjacent to large protrusion Z, it is not adjacent to large protrusion Y because large protrusion Z is between large protrusions Y and A. In other words, large protrusions Z and Y are not neighbors. In addition, large protrusion A is quite far from large protrusion Y—more than half of the maximum dimension of its base portion 40 (represented in FIG. 4A as a circle, discussed below). As another example, large protrusion A is not adjacent to large protrusion X because large protrusions Z and B are, at least in part, significantly between it and large protrusion X, and large protrusion A is far from large protrusion X (e.g., that distance is more than 50 percent or more than 75% of the maximum dimension of its base portion 40). In other words, as exemplified in FIG. 4A, large protrusion A clearly is not next to large protrusion X—they are not neighbors.

The protrusions 36A and 36B can take on any of a wide variety of shapes and sizes. In illustrative embodiments, the protrusions 36A and 36B are formed to minimize the amount of flat/planar regions on the top surface 34 of the substrate 18. To that end, as suggested above when discussing adjacency, each of the protrusions 36A and 36B may be considered to have a base portion 40 that intersects the flat portion 42 of the substrate 18. In illustrative embodiments, the base portions 40 of the large protrusions 36A have maximum outer dimensions that are substantially the same size. For simplicity, unless otherwise suggested, when generally discussing the size of a protrusion 36A and 36B, this description is referring to the maximum outer dimension of its base portion 40 (e.g., the diameter of the base portion 40 if shaped as a circle).

The base portions 40 of the large protrusions 36A preferably have maximum outer dimensions that are substantially the same size. In a similar manner, the base portions 40 of the small protrusions 36B preferably are substantially the same size, but smaller than those of the large protrusions 36A. Alternative embodiments may vary the sizes of the set of large protrusions 36A (i.e., the large protrusions 36A may have differing base portion sizes), and vary the sizes of the set of small protrusions 36B. When the sizes are varied within a given set, the small protrusions 36A preferably all are smaller than the sizes of the large protrusions 36A.

As suggested above, the base portions 40 also preferably are shaped to minimize flat portions 42 of the substrate 18. For example, the base portions 40 of the large protrusions 36A are generally round or elliptically shaped, as in the example of FIG. 4A, while the base portions 40 of the small protrusions 36B are generally triangular. In this case, the round bases of the large protrusions 36A should take up a maximum amount of space, while preferably minimizing the area of the interstitial regions 38A therebetween. Because the interstitial regions 38A are generally triangular shaped in this embodiment, forming the small protrusions 36B with triangularly shaped bases should also maximize coverage.

As better shown in FIG. 4B, the protrusions 36A and 36B preferably have one or more walls 44 extending upwardly from their base portions 40. In accordance with illustrative embodiments of the invention, these walls 44 are non-orthogonal with the flat portion 42 of the substrate 18. More specifically, those walls 44 preferably are oriented so that at least a portion of them form angles with the flat portion 42 that are greater than about 90 degrees. For example, FIG. 4B schematically shows a cross-section of those walls 44 of the large and small protrusions 36A and 36B as being generally smooth and planar, and respectively forming obtuse angles with the flat portion 42 of the substrate 18. For the large protrusions 36A, which have circular or elliptical base portions 40, those walls 44 may take on a generally rounded profile from the perspective of a horizontal-cross section (e.g., in addition to being a plan view, FIG. 4A also may be viewed as a horizontal cross-section at its base). A straight line tangent to a generally rounded wall 44 nevertheless preferably forms and obtuse angle with the generally flat portion 42 of the substrate 18 (as shown in FIG. 4B). Other embodiments, however, may take on other configurations. For example, the walls 44 may have convex portions or be entirely convex, flat portions 42 and non-flat portions, concave portions, or an irregular shape.

The protrusions 36A and 36B also may take on any of a wide variety of shapes and form factors. For example, the large protrusions 36A of FIGS. 4A and 4B may form generally rounded mounds, from a horizontal cross-sectional perspective (as noted above) that terminate at a peak. The small protrusions 36B, however, preferably take on a shape and form factor that appropriately fills in the space in the interstitial region 38A. For example, as shown in FIG. 4A, the small protrusions 36B may be in the form of three-sided pyramid with each of its three sides substantially planar. Indeed, like the large protrusions 36A, the small protrusions 36B may take on other shapes and form factors as required by their fabrication process and the application.

When designing the large and small protrusions 36A and 36B, those skilled in the art preferably select the appropriate shape, size, and other variables to increase the overall brightness of the LED die 16. As a demonstration, FIG. 4C schematically shows light beams reflecting from the substrate 18 (the multi-segmented arrows), and light beams absorbing into the substrate 18 (the vertical arrows striking the flat portion 42). Specifically, each of the reflected light beams first strikes a wall 44 of one of the protrusions 36A and 36B. Because of the angle of the first wall 44, the light beam reflects from the first wall 44 to the wall 44 of a neighboring protrusion 36A or 36B. For example, the left side of FIG. 4C shows a light beam that reflects from a wall 44 of a small protrusion 36B before striking the wall 44 of a large protrusion 36A. The light beam then reflects off the wall 44 of the large protrusion 36A and back upwardly. The other three exemplary reflected light beams have similar paths—they redirect generally downwardly directed light in a generally upward direction.

In contrast, the single segmented/straight light beams of FIG. 4C directly strike the substantially flat portion 42 of the substrate 18. The vast majority of these light beams undesirably absorb into the substrate 18. Accordingly, a small amount of light is reflected from these beams, but not shown. In a similar manner, a small amount of light is absorbed by the substrate 18 from the other three re-directed light beams, but, for simplicity, that absorbed light also is not shown. It should be noted that these beams of light are just illustrative and, indeed, those skilled in the art should understand that the substrate 18 may receive many more beams of light than those shown. In addition, some light beams may strike the walls 44 of the protrusions 36A and 36B and reflect downwardly into the flat portion 42. Accordingly, all light beams will not necessarily behave as shown in FIG. 4C.

The inventors recognized that the brightness produced by the overall LED die 16 increases as the total patterned area of the substrate 18 (i.e., the area having protrusions 36A and 36B) increases. Accordingly, illustrative embodiments may add even further protrusions 36C to the top surface 34. Specifically, despite having two types/sets of protrusions 36A and 36B, there may be a considerable amount of flat portion 42 (or flat area) remaining on the top surface 34 of the substrate 18. See, for example, FIGS. 4A and 4B, which show flat portions 42. Specifically, as shown in FIG. 4B, there still can be considerable flat portions 42 in the interstitial region 38A between two or more large protrusions 36A and a single small protrusion 36B. Undesirably, those flat portions 42 likely will continue to absorb a great deal of light incident on their surfaces. To mitigate this deficiency, illustrative embodiments further process the interstitial region 38A in an effort to minimize light absorption into many of those remaining flat portions 42 substrate 18. This smaller interstitial region, which may be considered to be a “nested interstitial region 38B” (i.e., part of the larger interstitial region 38A), nevertheless may be too small to fit another small protrusion 36B.

To overcome this problem, illustrative embodiments may form yet a third set of protrusions 36C (referred to as “mini-protrusions 36C” to differentiate them from the small protrusions 36B) having bases that are even smaller than those of the set of small protrusions 36B. FIG. 4D schematically shows one embodiment of these mini- protrusions 36C in the nested interstitial regions 38B between the small protrusions 36B and the large protrusions 36A. These nested interstitial regions 38B typically are between protrusions 36A and/or 36B of different sizes (at their bases). For example, the nested interstitial regions 38B of FIG. 4D are between large protrusions 36A and small protrusions 36B. In fact, illustrative embodiments may continue to nest protrusions (not shown) of progressively smaller base sizes in the various formed nested interstitial regions 38B within the larger interstitial region 38A. These nested protrusions may be considered to form a hierarchy.

In illustrative embodiments, the different sets of protrusions 36A-36C have different heights. For example, the large protrusions 36A are taller than the small protrusions 36B, while the small protrusions 36B are taller than the mini-protrusions 36C. Those skilled in the art, however, can modify the heights depending upon the process used to form the protrusions 36A-36C. For example, all of the different types of protrusions 36A/B/C may have the same height, or two different types of protrusions 36A/B/C may have the same height, while other types of protrusions 36A/B/C may have different types. Distinctions between the different types of protrusions 36A/B/C therefore may be their maximum outer dimension of its base portions 40, and their relative positions on the substrate 18.

The inventors also discovered that the protrusions 36A-36C produce additional performance benefits. Specifically, the flat portions 42 of the substrate 18 cause crystal dislocations in the buffer layer 22, which immediately contacts the protrusions 36A-36C and flat portions 42 (see FIG. 3). These dislocations in the buffer layer 22 undesirably reduce light transmission reflected from the substrate 18. Accordingly, reducing the total area of the flat portions 42 in this manner has the beneficial effect of minimizing the number of dislocations, which enhances the overall brightness of the LED die 16.

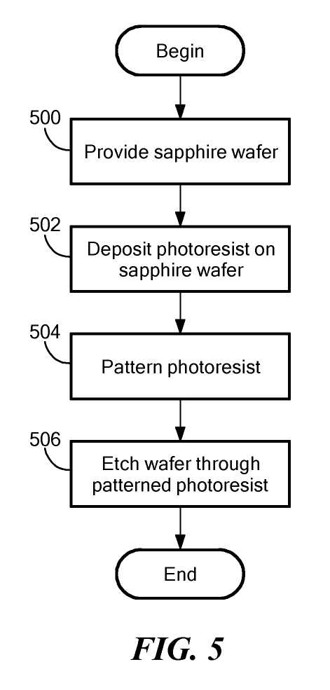

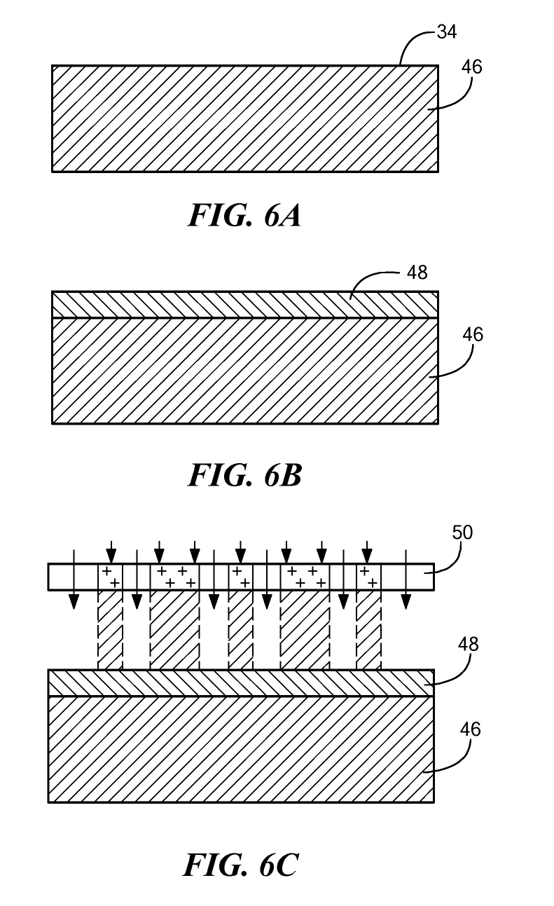

Those skilled in the art preferably use photolithographic fabrication techniques to pattern the top surface 34 of the substrate 18 in the above-described manner. To that end, FIG. 5 shows a process of patterning an oxide/sapphire wafer 46 in accordance with illustrative embodiments of the invention. FIGS. 6A-6C schematically show the substrate 18 at various stages of that process.

It should be noted that this process is substantially simplified from a longer process that normally would be used to pattern the substrate 18. Accordingly, the process of patterning the substrate 18 may have many additional steps (or sub-steps), such as testing steps or additional etching steps, which those skilled in the art may use. In addition, some of the steps may be performed in a different order than that shown, or at the same time. Those skilled in the art therefore can modify the process as appropriate. Moreover, as noted above and below, many of the materials and structures noted are but examples a wide variety of different materials and structures that may be used. Those skilled in the art can select the appropriate materials and structures depending upon the application and other constraints. Accordingly, discussion of specific materials and structures is not intended to limit all embodiments.

The process of FIG. 5 preferably uses bulk fabrication techniques, which form a plurality of patterned substrates 18 on the same oxide or sapphire wafer 46, or frame, at the same time. Although much less efficient, those skilled in the art can apply these principles to a process that patterns a single oxide or sapphire substrate 18.

The process of FIG. 5 begins at step 500, which provides a conventional sapphire wafer 46. FIG. 6A schematically shows a cross-sectional view of a conventional sapphire wafer 46 that may be used. As shown, this sapphire wafer 46 has an unpatterned or lightly patterned top surface 34, which may be generally planar.

The process then begins forming an etching mask (a patterned photoresist material 48, discussed below) on the top surface 34 of the sapphire wafer 46. Accordingly, to that end, step 502 deposits the noted photoresist material 48 on the top surface 34 of the wafer. FIG. 6B schematically shows the wafer at the stage of the process. Specifically, as known by those skilled in the art, photoresist is a light-sensitive material typically used for processing semiconductors.

In preferred embodiments, the photoresist material 48 is a positive photoresist material 48, in which the portions of the photoresist exposed to light are soluble. Accordingly, step 504 patterns the photoresist material 48 to form an etching mask. To that end, FIG. 6C schematically shows a positive mask 50 used to pattern the photoresist material 48 into the noted etching mask.

The positive mask 50 has a pattern of openings, like a template, to appropriately pattern the etching mask. For example, to form a substrate surface similar to that of FIGS. 4A and 4B, the positive mask 50 has openings for forming large protrusions 36A and small protrusions 36B. As another example, to form a substrate surface similar to that of FIG. 4D, the positive mask 50 has openings for forming large protrusions 36A, small protrusions 36B, and mini-protrusions 36C.

To complete step 504, conventional processes perform a light photolithography process to transfer the pattern of the positive mask 50 to the photoresist material 48 on the substrate 18. FIG. 6C schematically shows the mask 50 and hatched region, between the mask 50 and photoresist material 48 where light is blocked, and clear regions where light passes through the mask 50. Accordingly, at the conclusion of step 504, the photoresist material 48 has a pattern of holes that will be used for etchant.

The process continues to step 506, which etches the wafer through the patterned photoresist material 48 on the substrate 18. Among other ways, this step may use an inductively coupled plasma etcher to produce the desired pattern on the top surface 34 of the substrate 18 through the patterned photoresist material 48. In some embodiments, this step may involve a timed etch, an acid etchant, or a base etchant. The protrusions 36A-36C thus may be considered to be “photolithographic protrusions” because they are formed using photolithographic techniques and thus, have physical qualities specific to photolithography.

The process may execute additional steps after step 506. For example, the patterned photoresist material 48 preferably is removed from the top surface 34, and the layers forming the LEDs 20 may be added to form the LED dies 16. After forming the LED dies 16, conventional cutting processes (e.g., dicing or sawing processes) may separate the LED dies 16 to produce a plurality of independent LED dies 16.

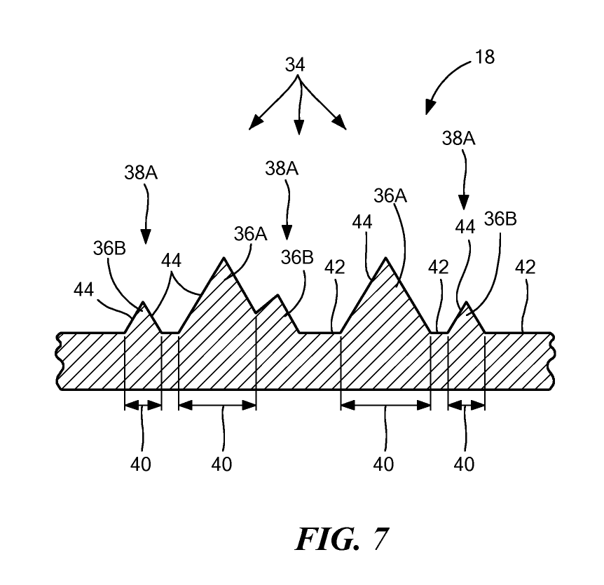

In alternative embodiments, one or more of the additional protrusions 36B and/or 36C may intersect or be part of one of one of the other protrusions (e.g., on one of protrusions 36A). FIG. 7, for example, shows one additional protrusion 36B may be formed on the slope of the larger protrusion 36A. As such, there may be no substantially planar/flat portion 42 between such a large protrusion 36A and an additional protrusion 36B. Accordingly, such larger protrusions 36A may be considered to have two (or more) peaks. For example, such a larger protrusion 36A may have a higher peak and several lower peaks. As another example, such a larger protrusion 36A may have multiple peaks with the same heights. The smaller protrusions 36C also may merge with other protrusions 36B and/or 36A in a similar manner.

Accordingly, etching the surface to form additional protrusions 36B and/or 36C within the interstitial region 38A is expected to redirect light that the LED 20 initially directs downwardly—that light is redirected upwardly. In addition, these protrusions 36B and 36C minimize flat portions 42 on the substrate 18, correspondingly reducing dislocations within the buffer layer 22. These improvements ultimately are expected to improve the brightness/effective output lumens of the LED die 16.

Although the above discussion discloses various exemplary embodiments of the invention, it should be apparent that those skilled in the art can make various modifications that will achieve some of the advantages of the invention without departing from the true scope of the invention.

1. A sapphire wafer comprising:
a patterned top surface of sapphire having a plurality of protrusions,
the plurality of protrusions including a set of first protrusions and a set of second protrusions,
at least three first protrusions being adjacent to each other and defining a primary interstitial region therebetween,
at least one of the second protrusions being in the primary interstitial region.

2. The sapphire wafer as defined by claim 1 wherein the top surface has a substantially flat portion, the first protrusions and the second protrusions each having walls that are non-orthogonal to the substantially flat portion of the top surface.

3. The sapphire wafer as defined by claim 2 wherein at least some of the walls form an angle of greater than about 90 degrees with the substantially flat portion of the top surface.

4. The sapphire wafer as defined by claim 1 wherein the first protrusions have a first height and the second protrusions have a second height, the first height being greater than the second height.

5. The sapphire wafer as defined by claim 1 wherein four protrusions form the primary interstitial region.

6. The sapphire wafer as defined by claim 1 wherein each of the at least three first protrusions includes two outer portions, a first of the two outer portions being adjacent to a first corresponding outer portion of one of the other first protrusions, a second of the two outer portions being adjacent to a second corresponding outer portion of another of the other first protrusions, the at least one second protrusion being between the at least three first protrusions.

7. The sapphire wafer as defined by claim 1 further comprising LED layers supported by the top surface to at least partly form an LED, the LED layers comprising gallium nitride.

8. The sapphire wafer as defined by claim 1 wherein the at least one second protrusion and at least one of the first protrusions forms a nested interstitial region therebetween, the primary interstitial region including the nested interstitial region, the top surface further comprising a set of third protrusions, at least one third protrusion being in the nested interstitial region.

9. The sapphire wafer as defined by claim 1 wherein each one of the at least three first protrusions has a base, the at least three first protrusions each having respective first maximum outer dimensions at their respective bases, the at least one second protrusion having a base and a second maximum outer dimension at its base, each of the first maximum outer dimensions being greater than each of the second maximum outer dimensions.

10. The sapphire wafer as defined by claim 1 wherein the top surface has a substantially flat portion, the first protrusions having a circular or elliptical shape along a plane parallel with the substantially flat portion.

11. The sapphire wafer as defined by claim 1 wherein one of the second protrusions intersects at least one of the three protrusions.

12. A sapphire wafer comprising:
a patterned top surface of sapphire having a substantially flat portion and a plurality of protrusions extending from the substantially flat portion,
the plurality of protrusions including a set of first protrusions and a set of second protrusions,
the first protrusions each having a first base intersecting the substantially flat portion, each first base having a first maximum outer dimension,
the second protrusions each having a second base intersecting the substantially flat portion, each second base having a second maximum outer dimension,
at least one of the second protrusions being between at least two first protrusions,
the first maximum outer dimensions of the at least two first protrusions being greater than the second maximum outer dimension of the at least one second protrusion.

13. The sapphire wafer as defined by claim 12 wherein the first and second protrusions are photolithographic protrusions.

14. The sapphire wafer as defined by claim 12 wherein the at least two first protrusions are adjacent to each other.

15. The sapphire wafer as defined by claim 14 wherein the at least two first protrusions comprises at least three first protrusions adjacent to each other and forming a primary interstitial region having the at least one second protrusion.

16. The sapphire wafer as defined by claim 12 the at least two first protrusions and the at least one second protrusion each have walls that are non-orthogonal to the substantially flat portion of the top surface, at least some of the walls forming an angle of greater than about 90 degrees with the substantially flat portion of the top surface.

17. The sapphire wafer as defined by claim 12 further comprising LED layers supported by the top surface to form an LED, the LED layers comprising gallium nitride.

18. The sapphire wafer as defined by claim 12 wherein the first and second protrusions form a repeating pattern across the patterned top surface of the sapphire wafer.

19. A method comprising:
providing an oxide wafer having a top surface of oxide; and
patterning the top surface to have a plurality of protrusions, the plurality of protrusions including a set of first protrusions and a set of second protrusions,
three first protrusions being adjacent to each other and defining a primary interstitial region therebetween, one of the second protrusions being in the primary interstitial region.

20. The method as defined by claim 19 wherein patterning comprises using a photolithographic process to pattern the top surface.

21. The method as defined by claim 19 wherein the oxide comprises sapphire.

22. The method as defined by claim 19 further comprising forming a plurality of additional layers on the top surface of the oxide to form a LED, at least one of the additional layers being an epitaxially grown layer in contact with the top surface.

23. The product formed by the method of claim 19.
